(19) United States
(12) Patent Application Publication
(10) Pub. No.: US 2011/0100464 A1
(43) Pub. Date: May 5, 2011

(54) Electrolyte composition and dye-sensitized solar cell using the same

(75) Inventors: Kuan-Wei Lee, Taoyuan Hsien (TW); Hsin-Yi Chen, Taoyuan Hsien (TW)

(73) Assignee: Everlight USA, Inc., Pineville, NC (US)

(21) Appl. No.: 12/654,999

(22) Filed: Jan. 13, 2010

(30) Foreign Application Priority Data
Oct. 30, 2009 (TW) 098136876

(51) Int. Cl. H01G 9/028; H01L 31/0256

(52) U.S. Cl. 136/263; 252/62.2

(57) ABSTRACT

The present invention relates to an electrolyte composition, including: (a) an organic amine hydroiodide, a metal iodide, an imidazolium salt or a combination thereof; (b) iodine; (c) guanidine thiocyanate; (d) a benzimidazole derivative, a pyridine derivative or a combination thereof; and (e) polyethylene glycol and propylene carbonate. Accordingly, the electrolyte composition provided by the present invention exhibits excellent photoelectric conversion efficiency and long-term stability, and is suitable for a dye-sensitized solar cell. The present invention further provides a dye-sensitized solar cell using the above-mentioned electrolyte composition.

### BACKGROUND OF THE INVENTION

1. Field of the Invention

The present invention relates to an electrolyte composition and, more particularly, to an electrolyte composition suitable for a dye-sensitized solar cell.

2. Description of Related Art

With the development of human civilization, the world faces some acute problems with regard to energy crisis and environmental contamination. In order to resolve the global energy crisis and reduce environmental contamination, photoelectric solar cells capable of transforming solar energy into electric power have been suggested as alternatives. Among solar cells, a dye-sensitized solar cell shows promise owing to its excellent properties. For example, it can be designed for production in large scale and has low manufacturing cost, flexibility, and optical transparency and thus can be applied on buildings.

Grätzel et al. have submitted a series of reports with regard to dye-sensitized solar cells to confirm their practicability (e.g. O'Regan, B.; Grätzel, M. Nature 1991, 353, 737). In general, a dye-sensitized solar cell includes: a cathode, an anode, nano titanium oxide, dyestuffs and an electrolyte, in which the electrolyte plays a critical role in efficiency of cells. In a dye-sensitized solar cell, an ideal electrolyte should be nonvolatile and capable of being easily packed, and have no leakage nor bad effects on dyestuffs and other components.

Based on the available knowledge, liquid electrolytes have higher photoelectric conversion efficiency. However, liquid electrolytes usually are volatile and incapable of being easily packed, and leakage of liquid electrolytes occurs easily. In order to obviate the aforementioned problems, researchers suggested, for example, ionic liquid (N. Papageorgiou et al., J. Electrochem. Soc, 1996, 143, 3099), and gel electrolyte consisting of polymers and organic molten salts (U.S. Pat. No. 6245847).

Since an electrolyte plays a critical role in efficiency of a dye-sensitized solar cell, one of the methods for improving efficiency of dye-sensitized solar cells is to provide an electrolyte capable of enhancing efficiency of dye-sensitized solar cells.

### SUMMARY OF THE INVENTION

The present invention provides a novel gel electrolyte composition suitable for a dye-sensitized solar cell. Owing to the excellent photoelectric conversion efficiency and long-term stability of the electrolyte composition according to the present invention, the dye-sensitized solar cell with the gel electrolyte composition according to the present invention used therein exhibits excellent photoelectric characteristics.

The present invention further provides a dye-sensitized solar cell, which has improved photoelectric conversion efficiency.

The present invention provides an electrolyte composition, including: (a) an organic amine hydroiodide, a metal iodide, an imidazolium salt or a combination thereof of 2-30% by weight; (b) iodine of 1-5% by weight; (c) guanidine thiocyanate (GuNCS) of 0.5-3% by weight; (d) a benzimidazole derivative, a pyridine derivative or a combination thereof of 2-10% by weight; and (e) polyethylene glycol (PEG) and propylene carbonate (PC) of 52-94.5% by weight. Preferably, the component (a) is 5-20% by weight; the component (b) is 1-3% by weight; the component (c) is 0.5-2% by weight; the component (d) is 5-10% by weight; and the component (e) is 65-88.5% by weight. Most preferably, the component (a) is 13.9% by weight; the component (b) is 2.1% by weight; the component (c) is 1% by weight; the component (d) is 7.2% by weight; and the component (e) is 75.8% by weight.

The organic amine hydroiodide of the above-mentioned component (a) may be triethylamine hydroiodide (THI), tripropylamine hydroiodide, tributylamine hydroiodide, tripentylamine hydroiodide, trihexylamine hydroiodide or a mixture thereof. Preferably, it is triethylamine hydroiodide, tripropylamine hydroiodide, tributylamine hydroiodide or a mixture thereof. Most preferably, it is triethylamine hydroiodide.

The metal iodide of the above-mentioned component (a) may be potassium iodide, lithium iodide, sodium iodide or a mixture thereof, and preferably is lithium iodide, sodium iodide or a mixture thereof.

The imidazolium salt of the above-mentioned component (a) may be 1-methyl-3-propylimidazolium iodide (PMII); 1,3-dimethylimidazolium iodide; 1-methyl-3-ethylimidazolium iodide; 1-methyl-3-butylimidazolium iodide; 1-methyl-3-pentyl-imidazolium iodide; 1-methyl-3-hexylimidazolium iodide; 1-methyl-3-heptylimidazolium iodide; 1-methyl-3-octylimidazolium iodide; 1,3-diethylimidazolium iodide; 1-ethyl-3-propylimidazolium iodide; 1-ethyl-3-butylimidazolium iodide; 1,3-propylimidazolium iodide; 1-propyl-3-butylimidazolium iodide or a mixture thereof. Preferably, it is 1-methyl-3-propylimidazolium iodide; 1-methyl-3-ethylimidazolium iodide; 1-methyl-3-butylimidazolium iodide; 1-methyl-3-pentyl-imidazolium iodide; 1-methyl-3-hexylimidazolium iodide; 1,3-diethylimidazolium iodide; 1-ethyl-3-propylimidazolium iodide; 1-ethyl-3-butylimidazolium iodide; 1,3-propylimidazolium iodide; 1-propyl-3-butylimidazolium iodide or a mixture thereof. More preferably, it is 1-methyl-3-propylimidazolium iodide; 1-methyl-3-ethylimidazolium iodide; 1-methyl-3-butylimidazolium iodide; 1-methyl-3-pentyl-imidazolium iodide; 1-methyl-3-hexylimidazolium iodide; 1,3-diethylimidazolium iodide; 1-ethyl-3-propylimidazolium iodide; 1-ethyl-3-butylimidazolium iodide or a mixture thereof. Most preferably, it is 1-methyl-3-propylimidazolium iodide; 1-methyl-3-ethylimidazolium iodide; 1-methyl-3-butylimidazolium iodide; 1-methyl-3-pentyl-imidazolium iodide; 1,3-diethylimidazolium iodide; 1-ethyl-3-propylimidazolium iodide or a mixture thereof.

The above-mentioned (d) the benzimidazole derivative, the pyridine derivative or the combination thereof may be N-methylbenzimidazole (NMBI), N-butylbenzimidazole (NBB), 4-tert-butylpyridine (4-TBP) or a mixture thereof.

The weight ratio of the polyethylene glycol to the propylene carbonate of the above-mentioned component (e) may be 20/80 to 40/60, and preferably is 25/75 to 35/65.

Besides, the present invention further provides a dye-sensitized solar cell, which includes the above-mentioned electrolyte composition. The dye-sensitized solar cell according to the present invention includes: a photoanode, including a dyestuff compound; a cathode; and an electrolyte layer, disposed between the photoanode and the cathode and including the above-mentioned electrolyte composition.

In the dye-sensitized solar cell according to the present invention, the photoanode includes: a transparent substrate, a transparent conductive film, a porous semiconductor film and a dyestuff compound.

In the dye-sensitized solar cell according to the present invention, the material of the transparent substrate of the photoanode is not particularly limited and any transparent material can be used. Preferably, the material of the transparent substrate is a transparent material capable of obstructing moisture and gas well from the outside of the dye-sensitized solar cell and having solvent resistance and weather resistance. Specifically, the transparent substrate includes: inorganic substrates, such as a quartz substrate, a glass substrate; and transparent plastic substrate, such as a polyethylene terephthalate (PET) substrate, a poly(ethylene naphthalene-2,6-dicarboxylate (PEN) substrate, a polycarbonate (PC) substrate, a polyethylene (PE) substrate, a polypropylene (PP) substrate, and a polyimide (PI) substrate. However, the transparent substrate is not limited thereto. In addition, the thickness of the transparent substrate is not particularly limited and can be designed based on transparency and characteristics of the dye-sensitized solar cell. Preferably, the transparent substrate is made of glass.

In the dye-sensitized solar cell according to the present invention, the material of the transparent conductive film may be indium tin oxide (ITO), fluorine-doped tin oxide (FTO), ZnO—Ga₂O₃, ZnO—Al₂O₃, or tin-based oxides.

In the dye-sensitized solar cell according to the present invention, the porous semiconductor film may be made of semiconductor microparticles. The suitable microparticles may include: silicon microparticles, titanium dioxide microparticles, tin dioxide microparticles, zinc oxide microparticles, tungsten trioxide microparticles, niobium pentoxide microparticles, strontium titanium trioxide microparticles, and a combination thereof. Preferably, the semiconductor microparticles are titanium dioxide microparticles. The semiconductor microparticles may be 5 to 500 nanometers in average diameter, and preferably is 10 to 50 nanometers. The porous semiconductor film may be 5 to 25 micrometers in thickness.

Additionally, the material of the cathode used in the dye-sensitized solar cell is not particularly limited and may include any conductive material. Alternatively, the cathode is made of an insulating material and a conductive layer is formed on its surface that faces the photoanode. Any electrochemically stable material may be used in the cathode, and the suitable material of the cathode, for example, includes: platinum, gold, carbon, and the like.

In the dye-sensitized solar cell, the electrolyte composition according to the present invention is used as the electrolyte layer.

### BRIEF DESCRIPTION OF THE DRAWINGS

None

### DETAILED DESCRIPTION OF THE PREFERRED EMBODIMENT

Metal iodides (such as LiI, NaI, KI and so on), organic amine hydroiodides (such as THI, TEAI and so on) and imidazolium salts (such as PMII, EMII and so on) are used either in single or mixture, together with N-butylbenzimidazole (or N-methylbenzimidazole or 4-tert-butylpyridine) and guanidine thiocyanate, and polyethylene glycol (PEG) of 20 wt %-40 wt % and propylene carbonate (PC) of 80 wt %-60 wt % are used as gel solvent to prepare an electrolyte composition in a suitable concentration.

The method for fabricating a dye-sensitized solar cell according to the present invention is not particularly limited, and can be any conventional method.

The material of the transparent substrate is not particularly limited and can be any transparent material. Preferably, the material of the transparent substrate is a transparent material capable of obstructing moisture and gas well from the outside of the dye-sensitized solar cell and having solvent resistance and weather resistance. Specifically, the transparent substrate includes: inorganic substrates, such as a quartz substrate, a glass substrate; and transparent plastic substrate, such as a polyethylene terephthalate (PET) substrate, a poly(ethylene naphthalene-2,6-dicarboxylate (PEN) substrate, a polycarbonate (PC) substrate, a polyethylene (PE) substrate, a polypropylene (PP) substrate, and a polyimide (PI) substrate. However, the transparent substrate is not limited thereto. The thickness of the transparent substrate is not particularly limited and can be designed based on transparency and characteristics of the dye-sensitized solar cell. In an embodiment, the transparent substrate is a glass substrate.

The material of the transparent conductive film may be selected from the group consisting of indium tin oxide (ITO), fluorine-doped tin oxide (FTO), ZnO—Ga₂O₃, ZnO—Al₂O₃, and tin-based oxides. In an embodiment, the transparent conductive film is made of fluorine-doped tin oxide.

The porous semiconductor film is made of semiconductor microparticles. The suitable microparticles may include: silicon microparticles, titanium dioxide microparticles, tin dioxide microparticles, zinc oxide microparticles, tungsten trioxide microparticles, niobium pentoxide microparticles, strontium titanium trioxide microparticles, and a combination thereof.

The semiconductor microparticles are first prepared in a paste form and coated on the transparent substrate. Herein, a common wet coating process can be performed, such as blade coating, screen printing, spin coating and spray coating. In addition, the coating process can be carried out one or more times to achieve suitable thickness. The semiconductor film may be mono-layered or multi-layered. Herein, the term “multi-layer” refers to that the diameters of semiconductor microparticles in different layers are various. For example, the semiconductor microparticles of 5 to 50 nanometers may be first coated in a thickness of 5 to 20 micrometers, and then the semiconductor microparticles of 200 to 400 nanometers are coated in a thickness of 3 to 5 micrometers. After drying at a temperature in a range of 50 to 100° C., sintering at a temperature in a range of 400 to 500° C. is carried out for 30 minutes so as to obtain a multi-layered semiconductor film.

The dyestuffs (such as N719) can be dissolved in a suitable solvent to prepare a dyestuff solution. The suitable solvent includes: acetonitrile, methanol, ethanol, propanol, butanol, dimethylformide, N-methyl pyrrolidone or a mixture thereof. However, it is not limited thereto. Herein, the transparent substrate coated with the semiconductor film is dipped in a dyestuff solution until the transparent substrate thoroughly absorbs dyestuffs in the dyestuff solution, followed by drying. Accordingly, a photoanode of a dye-sensitized solar cell is obtained.

The material of the cathode is not particularly limited and may include any conductive material. Alternatively, the cathode is made of an insulating material and a conductive layer is formed on its surface that faces the photoanode. In addition, any electrochemically stable material may be used in the cathode, and the suitable material of the cathode, for example, includes: platinum, gold, carbon, and the like.

The electrolyte composition according to the present invention is used in the electrolyte layer.

The method for preparing a dye-sensitized solar cell according to the present invention is specifically described as follows.

First, a paste containing titanium oxide microparticles of 20-30 nanometers in diameter is coated on a glass substrate covered by fluorine-doped tin oxide (FTO) by screen printing one or more times, followed by sintering at 450° C. for 30 minutes.

Dyestuffs are dissolved in a mixture of acetonitrile and t-butanol (1:1 v/v) to prepare a dyestuff solution. Subsequently, the above glass substrate containing the porous titanium oxide film is dipped in the dyestuff solution until the dyestuffs are thoroughly absorbed, followed by drying. Accordingly, a photoanode is obtained.

The glass substrate covered by fluorine-doped tin oxide is drilled to form a hole of 0.75 millimeter in diameter for the electrolyte composition to be injected therethrough. Next, the glass substrate covered by fluorine-doped tin oxide is coated with the H₂PtCl₆ solution, followed by heating at 400° C. for 15 minutes, so as to form a cathode.

Then, thermoplastic polymer film of 60 micrometers in thickness is disposed between the photoanode and the cathode. At a temperature of 120 to 140° C., a pressure is applied on the two electrodes to combine them.

The electrolyte composition according to the present invention is injected into the hole, and then the hole is sealed with the thermoplastic polymer film so as to obtain the dye-sensitized solar cell according to the present invention.

These following examples are provided for explaining the present invention. The scope of the present invention is not limited thereto.

### Examples 1-5 and Comparative Examples 1-4

In Comparative Examples 1-4 and Examples 1-5, metal iodides (such as LiI, NaI, KI and so on), organic amine hydroiodides (such as THI, TEAI and so on) and imidazolium iodides (such as PMII, EMII and so on) are used either in single or mixture, together with N-butylbenzimidazole (or N-methylbenzimidazole or 4-tert-butylpyridine) and guanidine thiocyanate (GuNCS), and polyethylene glycol (PEG) of 20 wt %-40 wt % and propylene carbonate (PC) of 80 wt %-60 wt % are used as gel solvent.

The electrolyte components of Comparative Examples 1-4 and Examples 1-5 are listed in Tables 1 and 3. In photoelectric effect tests, the electrolyte compositions of Comparative Examples 1-4 and Examples 1-5 are used for preparing dye-sensitized solar cell, and short circuit current (J_{SC}), open circuit voltage (V_{OC}), photoelectric conversion efficiency (η) and fill factor (FF) are measured at illumination of AM 1.5. The results are shown in Tables 2 and 4.

TABLE 1

| | Comparative | Comparative | | | |
|---|---|---|---|---|---|
| Item | Example 1 | Example 2 | Example 1 | Example 2 | Example 3 |
| PMII | X | 0.65M | 0.65M | 0.65M | 0.65M |
| KI | 0.65M | X | X | 0.15M | X |
| THI | X | X | X | X | 0.15M |
| I₂ | 0.065M | 0.065M | 0.065M | 0.065M | 0.065M |
| NBB | X | X | 0.5M | 0.5M | 0.5M |
| GuNCS | X | X | 0.1M | 0.1M | 0.1M |
| Solvent | 40 wt % PEG/ | 40 wt % PEG/ | 40 wt % PEG/ | 40 wt % PEG/ | 40 wt % PEG/ |
| | 60 wt % PC | 60 wt % PC | 60 wt % PC | 60 wt % PC | 60 wt % PC |

TABLE 2

| | Comparative | Comparative | | | |
|---|---|---|---|---|---|
| Item | Example 1 | Example 2 | Example 1 | Example 2 | Example 3 |
| V_{OC} | 0.761 | 0.775 | 0.780 | 0.786 | 0.725 |
| (V) | | | | | |
| J_{SC} | 6.44 | 6.03 | 6.99 | 7.14 | 7.94 |
| (mA/ | | | | | |
| cm²) | | | | | |
| FF | 52.81 | 63.48 | 59.40 | 55.01 | 56.76 |
| η (%) | 2.59 | 2.97 | 3.24 | 3.08 | 3.27 |

The composition of Comparative Example 1 is conventional, which consists of KI and I₂ as main components and PEG/PC as gel solvent. The composition of Comparative Example 2 consists of imidazolium iodide and I₂ as main components, and its efficiency is higher than that of Comparative Example 1. In Examples 1-3, metal iodides (such as LiI, NaI, KI and so on), organic amine hydroiodides (such as THI, TEAI and so on) and imidazolium iodides (such. as PMII, EMII and so on) are used either in single or mixture, together with N-butylbenzimidazole (or N-methylbenzimidazole or 4-tert-butylpyridine) and guanidine thiocyanate (GuNCS), and polyethylene glycol (PEG) of 20 wt %-40 wt % and propylene carbonate (PC) of 80 wt %-60 wt % are used as gel solvent. The efficiency of Examples 1-3 is higher than that of Comparative Examples 1-2.

TABLE 3

| | Comparative | Comparative | | |
|---|---|---|---|---|
| Item | Example 3 | Example 4 | Example 4 | Example 5 |
| PMII | 0.65M | 0.65M | 0.65M | 0.65M |
| KI | X | X | 0.15M | X |
| THI | X | X | X | 0.15M |
| I₂ | 0.65M | 0.65M | 0.65M | 0.65M |
| NBB | 0.5M | X | 0.5M | 0.5M |
| GuNCS | 0.1M | X | 0.1M | 0.1M |
| solvent | 3-MPN | 30 wt % PEG/ | 30 wt % PEG/ | 30 wt % PEG/ |
| | | 70 wt % PC | 70 wt % PC | 70 wt % PC |

TABLE 4

| | Comparative | Comparative | | |
|---|---|---|---|---|
| Item | Example 3 | Example 4 | Example 4 | Example 5 |
| V_{OC} (V) | 0.74 | 0.72 | 0.80 | 0.75 |
| J_{SC} | 7.62 | 6.19 | 6.95 | 7.56 |
| (mA/cm²) | | | | |
| FF | 65.4 | 63.8 | 63.4 | 60.3 |
| η (%) | 3.69 | 2.85 | 3.50 | 3.40 |

Comparative Example 3 uses a commonly used liquid electrolyte, where 3-MPN is used as a solvent. In Examples 4-5, metal iodides (such as LiI, NaI, KI and so on), organic amine hydroiodides (such as THI, TEAI and so on) and imidazolium iodides (such as PMII, EMII and so on) are used either in single or mixture, together with N-butylbenzimidazole (or N-methylbenzimidazole or 4-tert-butylpyridine) and guanidine thiocyanate (GuNCS), and polyethylene glycol (PEG) of 30 wt % and propylene carbonate (PC) of 70 wt % are used as gel solvent. The efficiency of Examples 4-5 is about 77%-95% of the liquid electrolyte (Comparative Example 3).

In a dye-sensitized solar cell, electrolyte is associated with oxidation-reduction reaction. Efficiency and stability of a dye-sensitized solar cell depends on electrolyte components. Accordingly, an electrolyte consisting of components for enhancement of current and voltage and high boiling point solvent may exhibit high electrochemical stability. In addition to commonly-used metal iodides (such as LiI, NaI, KI and so on), the present invention further uses organic amine hydroiodide (such as THI, TEAI and so on) as well as imidazolium iodides (such as PMII, EMII and so on), N-butylbenzimidazole (or N-methylbenzimidazole or 4-tert-butylpyridine), guanidine thiocyanate and gel solvent of high boiling point and high viscosity, such that an electrolyte composition with high chemical stability can be obtained. Accordingly, high photoelectric conversion efficiency and long-term stability can be achieved.

Although the present invention has been explained in relation to its preferred embodiment, it is to be understood that many other possible modifications and variations can be made without departing from the scope of the invention as hereinafter claimed.

What is claimed is:

1. An electrolyte composition, comprising:
(a) an organic amine hydroiodide, a metal iodide, an imidazolium salt or a combination thereof of 2-30% by weight;
(b) iodine of 1-5% by weight;
(c) guanidine thiocyanate of 0.5-3% by weight;
(d) a benzimidazole derivative, a pyridine derivative or a combination thereof of 2-10% by weight; and
(e) polyethylene glycol and propylene carbonate of 52-94.5% by weight.

2. The electrolyte composition as claimed in claim 1, wherein the component (a) is the organic amine hydroiodide.

3. The electrolyte composition as claimed in claim 1, wherein the component (a) is the metal iodide.

4. The electrolyte composition as claimed in claim 1, wherein the component (a) is the imidazolium salt.

5. The electrolyte composition as claimed in claim 2, wherein (a) the organic amine hydroiodide is triethylamine hydroiodide, tripropylamine hydroiodide, tributylamine hydroiodide, tripentylamine hydroiodide, trihexylamine hydroiodide or a mixture thereof.

6. The electrolyte composition as claimed in claim 3, wherein (a) the metal iodide is potassium iodide, lithium iodide, sodium iodide or a mixture thereof.

7. The electrolyte composition as claimed in claim 4, wherein (a) the imidazolium salt is 1-methyl-3-propylimidazolium iodide; 1,3-dimethylimidazolium iodide; 1-methyl-3-ethylimidazolium iodide; 1-methyl-3-butylimidazolium iodide; 1-methyl-3-pentyl-imidazolium iodide; 1-methyl-3-hexylimidazolium iodide; 1-methyl-3-heptylimidazolium iodide; 1-methyl-3-octylimidazolium iodide; 1,3-diethylimidazolium iodide; 1-ethyl-3-propylimidazolium iodide; 1-ethyl-3-butylimidazolium iodide; 1,3-propylimidazolium iodide; 1-propyl-3-butylimidazolium iodide or a mixture thereof.

8. The electrolyte composition as claimed in claim 5, wherein (d) the benzimidazole derivative, the pyridine derivative or the combination thereof is N-methylbenzimidazole, N-butylbenzimidazole, 4-tert-butylpyridine or a mixture thereof.

9. The electrolyte composition as claimed in claim 1, wherein the weight ratio of the polyethylene glycol to the propylene carbonate of the component (e) is 20/80 to 40/60.

10. The electrolyte composition as claimed in claim 5, wherein the weight ratio of the polyethylene glycol to the propylene carbonate of the component (e) is 20/80 to 40/60.

11. The electrolyte composition as claimed in claim 8, wherein the weight ratio of the polyethylene glycol to the propylene carbonate of the component (e) is 20/80 to 40/60.

12. The electrolyte composition as claimed in claim 11, wherein the component (a) is 13.9% by weight; the component (b) is 2.1% by weight; the component (c) is 1% by weight; the component (d) is 7.2% by weight; and the component (e) is 75.8% by weight.

13. A dye-sensitized solar cell, comprising:
(A) a photoanode;
(B) a cathode; and
(C) an electrolyte layer, comprising: (a) an organic amine hydroiodide, a metal iodide, an imidazolium salt or a combination thereof; (b) iodine; (c) guanidine thiocyanate; (d) a benzimidazole derivative, a pyridine derivative or a combination thereof; and (e) polyethylene glycol and propylene carbonate.

14. The dye-sensitized solar cell as claimed in claim 13, wherein the organic amine hydroiodide of the component (a) is triethylamine hydroiodide, tripropylamine hydroiodide, tributylamine hydroiodide tripentylamine hydroiodide, trihexylamine hydroiodide or a mixture thereof.

15. The dye-sensitized solar cell as claimed in claim 13, wherein the metal iodide of the component (a) is potassium iodide, lithium iodide, sodium iodide or a mixture thereof.

16. The dye-sensitized solar cell as claimed in claim 13, wherein the imidazolium salt of the component (a) is 1-methyl-3-propylimidazolium iodide; 1,3-dimethylimidazolium iodide; 1-methyl-3-ethylimidazolium iodide; 1-methyl-3-butylimidazolium iodide; 1-methyl-3-pentyl-imidazolium iodide; 1-methyl-3-hexylimidazolium iodide; 1-methyl-3-heptylimidazolium iodide; 1-methyl-3-octylimidazolium iodide; 1,3-diethylimidazolium iodide; 1-ethyl-3-propylimidazolium iodide; 1-ethyl-3-butylimidazolium iodide; 1,3-propylimidazolium iodide; 1-propyl-3-butylimidazolium iodide or a mixture thereof.

17. The dye-sensitized solar cell as claimed in claim 13, wherein the weight ratio of the polyethylene glycol to the propylene carbonate of the component (e) is 20/80 to 40/60.

18. The dye-sensitized solar cell as claimed in claim 14, wherein the weight ratio of the polyethylene glycol to the propylene carbonate of the component (e) is 20/80 to 40/60.
